(19) United States
(12) Patent Application Publication
(10) Pub. No.: US 2026/0179550 A1
(43) Pub. Date: Jun. 25, 2026

(54) DISPLAY DEVICE

(71) Applicant: LG Display Co., Ltd., Seoul (KR)

(72) Inventors: SeungHo HEO, Paju-si (KR); KiBok PARK, Paju-si (KR)

(73) Assignee: LG Display Co., Ltd., Seoul (KR)

(21) Appl. No.: 19/310,510

(22) Filed: Aug. 26, 2025

(30) Foreign Application Priority Data
Dec. 24, 2024 (KR) 10-2024-0195969

(51) Int. Cl. G09G 3/3233; G09G 3/00; G09G 3/32

(52) U.S. Cl. CPC G09G 3/3233; G09G 3/006; G09G 3/32; G09G 2300/0413; G09G 2300/0842

(57) ABSTRACT

The present disclosure provides a display device that includes a structure where a reference voltage line is electrically connected to first to third subpixels, and a first gate line is electrically connected to the first to third subpixels located in a diagonal direction, and is capable of improving the quality of a display pane.

### CROSS REFERENCE TO RELATED APPLICATION

This application claims priority from Korean Patent Application No. 10-2024-0195969, filed on Dec. 24, 2024 in the Korean Intellectual Property Office, which is hereby incorporated by reference for all purposes as if fully set forth herein.

### BACKGROUND

### Technical Field

The present disclosure relates to electronic devices, and more specifically, to display devices.

### Description of the Related Art

In today's information society, display devices for presenting images or visual information to users are increasingly important. The various needs for display devices has caused display technology to be rapidly developed, and indeed, various types of display devices, such as a liquid crystal display (LCD) device, an organic light emitting display (OLED) device, an inorganic light emitting display (iLED) device, a micro light emitting display (micro LED) device, a mini light emitting displays (mini LED) device, a quantum dot light emitting display (QLED) device, and the like, have been developed and widely used.

Display devices may include a plurality of subpixels. The plurality of subpixels may be arranged in a matrix form.

### BRIEF SUMMARY

One or more aspects of the present disclosure may provide a display device that includes a structure where a gate line at least partially extents along subpixels disposed in different rows, and is capable of improving the image display quality of a display panel.

One or more aspects of the present disclosure may provide a display device that includes a structure where a gate line at least partially extents along subpixels disposed in different rows, and is capable of detecting characteristic values of subpixels and improving the image display quality of a display panel.

One or more aspects of the present disclosure may provide a display device that includes a structure where a gate line at least partially extents along subpixels disposed in different rows, and is capable of driving a display panel in a simplified configuration and driving the display panel with low power.

Aspects, examples, and embodiments provided in the present disclosure are not limited to the foregoing description, and additional aspects, examples, and embodiments provided in the present disclosure will become apparent to those skilled in the art from the following description.

According to one or more example embodiments of the present disclosure, a display device can be provided that includes a plurality of subpixels, a plurality of gate lines connected to the plurality of subpixels, and a plurality of reference voltage lines connected to the plurality of subpixels. In one or more aspects, the plurality of reference voltage lines may include a reference voltage line electrically connected to first to third subpixels, and the plurality of gate lines may include a first gate line electrically connected to the first to third subpixels disposed in a diagonal direction.

According to one or more aspects of the present disclosure, a display device may be provided that is capable of improving the image display quality of a display panel by including a structure where a gate line at least partially extents along subpixels disposed in different rows.

According to one or more aspects of the present disclosure, a display device may be provided that is capable of detecting characteristic values of subpixels and improving the image display quality of a display panel by including a structure where a gate line at least partially extents along subpixels disposed in different rows.

According to one or more aspects of the present disclosure, a display device may be provided that is capable of driving a display panel in a simplified configuration and driving the display panel with low power by including a structure where a gate line at least partially extents along subpixels disposed in different rows.

Effects or advantages from aspects, examples, and embodiments described herein are not limited thereto, and additional effects or advantages will become apparent to those skilled in the art from the following description.

### BRIEF DESCRIPTION OF THE SEVERAL VIEWS OF THE DRAWINGS

The accompanying drawings, which are included to provide a further understanding of the disclosure and are incorporated in and constitute a part of the disclosure, illustrate aspects of the disclosure and together with the description serve to explain principles of the disclosure. It should be therefore understood that aspects, examples, and embodiments described herein are not limited to the illustrations of the accompanying drawings. In the drawings:

FIG. 1 illustrates an example configuration of a display device according to aspects of the present disclosure;

FIG. 2 illustrates an example equivalent circuit of a subpixel included in the display device according to aspects of the present disclosure;

FIG. 3 illustrates an example compensation circuit included in the display device according to aspects of the present disclosure;

FIG. 4 illustrates an example first sensing mode of the display device according to aspects of the present disclosure;

FIG. 5 illustrates an example second sensing mode of the display device according to aspects of the present disclosure;

FIG. 6 illustrates example sensing timings of the display device according to aspects of the present disclosure;

FIG. 7 illustrates an example configuration of a plurality of subpixels in a display panel according to aspects of the present disclosure;

FIG. 8 illustrates an example structure of a plurality of subpixels according to aspects of the present disclosure;

FIG. 9 illustrates an example characteristic value sensing for subpixels according to aspects of the present disclosure; and

FIGS. 10 and 11 illustrate example light emitting states of the display panel.

### DETAILED DESCRIPTION

Reference will now be made in detail to example embodiments of the present disclosure, examples of which may be illustrated in the accompanying drawings.

In the following description, the structures, embodiments, implementations, methods and operations described herein are not limited to the specific example or examples set forth herein and may be changed as is known in the art, unless otherwise specified. Like reference numerals designate like elements throughout, unless otherwise specified. Names of the respective elements used in the following explanations are selected only for convenience of writing the specification and may thus be different from those used in actual products. Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure. Further, the protected scope of the present disclosure is defined by claims and their equivalents. In the following description, where the detailed description of the relevant known function or configuration may unnecessarily obscure aspects of the present disclosure, a detailed description of such known function or configuration may be omitted. The shapes, sizes, ratios, angles, numbers, and the like, which are illustrated in the drawings to describe various example embodiments of the present disclosure, are merely given by way of example. Therefore, the present disclosure is not limited to the illustrations in the drawings. The terms such as “including,” “having,” “containing,” “constituting” “make up of,” and “formed of” used herein are generally intended to allow other components to be added unless the terms are used with the term “only.” As used herein, singular forms are intended to include plural forms unless the context clearly indicates otherwise.

Although the terms “first,” “second,” A, B, (a), (b), and the like may be used herein to describe various elements, these elements should not be interpreted to be limited by these terms as they are not used to define a particular order or precedence. These terms are used only to distinguish one element from another. For example, a first element could be termed a second element, and, similarly, a second element could be termed a first element, without departing from the scope of the present disclosure.

When it is mentioned that a first element “is connected or coupled to,” “contacts,” “overlaps with,” or the like a second element, it should be interpreted that, not only can the first element “be directly connected or coupled to,” “directly contact,” or “directly overlap with” the second element, but a third element can also be “interposed” between the first and second elements, or the first and second elements can “be connected or coupled to,” “contact,” “overlap with,” or the like each other via a fourth element. Here, the second element may be included in at least one of two or more elements that “are connected or coupled to,” “contact,” “overlap with,” or the like each other.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third element or layer may be interposed therebetween. Furthermore, the terms “left,” “right,” “top,” “bottom, “downward,” “upward,” “upper,” “lower,” and the like refer to an arbitrary frame of reference.

In addition, when any dimensions, relative sizes, and the like are mentioned, it should be considered that numerical values for an elements or features, or corresponding information (e.g., level, range, and the like) include a tolerance or error range that may be caused by various factors (e.g., process factors, internal or external impact, noise, and the like) even when a relevant description is not specified. Further, the term “may” fully encompasses all the meanings of the term “can”.

In the following description, various example aspects of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, aspects of the present disclosure are not limited to a scale, dimension, size, and thickness illustrated in the drawings.

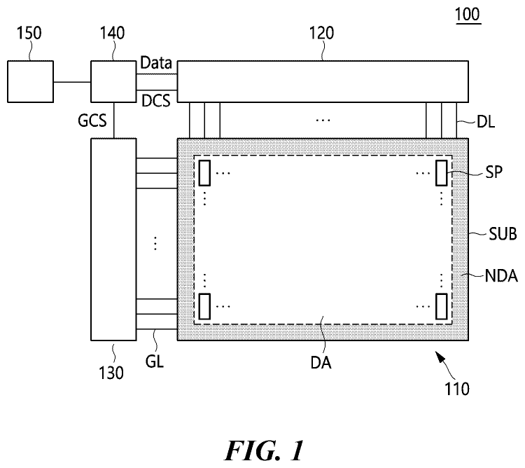

FIG. 1 illustrates an example configuration of a display device 100 according to aspects of the present disclosure. All components of each display device according to all aspects of the present disclosure are operatively coupled and configured.

Referring to FIG. 1, in one or more example embodiments, a display device 100 may include a display panel 110 and at least one driving circuit for driving the display panel 110.

The at least one driving circuit may include a data driving circuit 120, a gate driving circuit 130, and the like, and further include a controller 140 for controlling the data driving circuit 120 and the gate driving circuit 130.

The display panel 110 may include a substrate SUB, and signal lines such as a plurality of data lines DL, a plurality of gate lines GL, and the like, which are disposed on the substrate SUB. The display panel 110 may include a plurality of subpixels SP connected to the plurality of data lines DL and the plurality of gate lines GL.

The display panel 110 may include a display area DA in which one or more images can be displayed and a bezel area BA in which an image is not displayed. In the display panel 110, the plurality of subpixels SP for displaying images may be disposed in the display area DA, and a pad part where the driving circuits (120, 130, 140) may be electrically connected or mounted may be disposed in the non-display area NDA. For example, an integrated circuit or a printed circuit may be disposed in the pad part.

The data driving circuit 120 may be a circuit for driving the plurality of data lines DL and can supply data signals (which may be referred to as data voltages) to the plurality of data lines DL. The gate driving circuit 130 may be a circuit for driving the plurality of gate lines GL and can supply gate signals to the plurality of gate lines GL. The controller 140 can supply a data control signal DCS to the data driving circuit 120 to control an operation timing of the data driving circuit 120. The controller 140 can supply a gate control signal GCS to the gate driving circuit 130 to control an operation timing of the gate driving circuit 130.

The controller 140 can start to scan pixels according to respective timings set in each frame, convert image data received from an external device or system (e.g., a host system) to image data Data with a data signal form readable by the data driving circuit 120, then supply image data Data resulting from the converting to the data driving circuit 120, and control the operation of data driving circuit 120 at timings set for scanning corresponding one or more pixels.

The timing controller 140 can receive several types of timing signals including a vertical sync signal VSYNC, a horizontal sync signal HSYNC, an input data enable signal Data Enable, a clock signal CLK, and the like, along with image data from the external device or system (e.g., the host system).

The controller 140 can output various data control signals DCS including a source start pulse SSP, a source sampling clock SSC, a source output enable signal SOE, and the like to control the data driving circuit 120.

The controller 140 may be implemented in a separate component from the data driving circuit 120, or integrated with the data driving circuit 120, so that the controller 140 and the data driving circuit 120 can be implemented in a single integrated circuit.

The data driving circuit 120 can drive a plurality of data lines DL by receiving image data Data from the controller 140 and then supplying data voltage to the plurality of data lines DL. The data driving circuit 120 may also be referred to as a source driving circuit. The data drive circuits 120 may include one or more source driver integrated circuits SDIC.

The gate driving circuit 130 can supply a gate signal of a turn-on level voltage, a gate signal of a turn-off level voltage, or a gate signal with a turn-on level and a turn-off level according to the control of the timing controller 140. The gate driving circuit 130 can sequentially drive a plurality of gate lines GL by sequentially supplying gate signals of the turn-on level voltage to the plurality of gate lines GL.

The gate driving circuit 130 included in the display device 100 may be disposed in the non-display area NDA of the display panel 110 by a gate-in-panel (GIP) technique. The gate driving circuit 130 may be disposed on a substrate SUB, or connected to the substrate SUB. In an example where the gate driving circuit 130 is implemented in the display device 100 by the gate-in-panel (GIP) technique, the gate driving circuit 130 may be disposed in the non-display area NDA of the substrate SUB. The gate driving circuit 130 may be attached to the substrate SUB when the gate driving circuit 130 is implemented by the chip-on-glass (COG) technique, the chip-on-film (COF) technique, or the like.

At least one of the data driving circuit 120 and the gate driving circuit 130 may be disposed in the display area DA. For example, at least one of the data driving circuit 120 and the gate driving circuit 130 may be disposed not to overlap with subpixels SP, or be disposed to overlap with one or more, or all, of the subpixels SP.

The controller 140 may be mounted on a printed circuit board, a flexible printed circuit, or the like, and may be electrically connected to the data driving circuit 120 and the gate driving circuit 130 through the printed circuit board, the flexible printed circuit, and/or the like.

In one or more aspects, the display device 100 may be a display including a backlight unit, such as a liquid crystal display (LCD) and the like, or be a self-emissive display, such as an organic light emitting diode (OLED) display, a quantum dot display, a micro light emitting diode (LED) display, and the like.

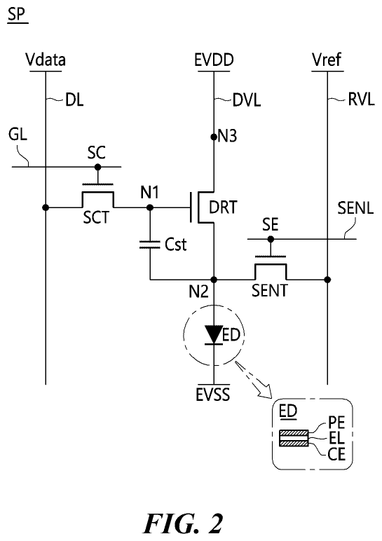

FIG. 2 illustrates an example equivalent circuit of a subpixel SP included in the display device 100 according to aspects of the present disclosure.

Referring to FIG. 2, in one or more example embodiments, each of a plurality of subpixels SP disposed on the display panel 110 of the display device 100 may include a light emitting element ED, a driving transistor DRT, a scan transistor SCT, a sensing transistor SENT, and a storage capacitor Cst.

Referring to FIG. 2, the light emitting element ED may include a pixel electrode PE and a common electrode CE, and include an emission layer EL located between the pixel electrode PE and the common electrode CE.

The pixel electrode PE of the light emitting element ED may be an electrode disposed for each subpixel SP, and the common electrode CE may be an electrode commonly disposed for all or some of the plurality subpixels SP. The pixel electrode PE may be an anode electrode, and the common electrode CE may be a cathode electrode.

The driving transistor DRT may be a transistor for driving the light emitting element ED, and a gate electrode of the driving transistor DRT may be connected to a first node N1, a source electrode may be connected to a second node N2, and a drain electrode may be connected to a third node N3. The first node N1 may be electrically connected to a source electrode or drain electrode of the scan transistor SCT, and the second node N2 may be electrically connected to the pixel electrode PE of the light emitting element ED. The third node N3 may be electrically connected to a driving voltage line DVL for delivering a driving voltage EVDD. The driving transistor DRT may be controlled by a voltage of the first node N1, and when turned on, can apply the driving voltage EVDD to the second node N2.

The scan transistor SCT may be controlled by a scan signal SC, which is a type of gate signal, and may be connected between the gate electrode of the driving transistor DRT and a data line DL. A gate electrode of the scan transistor SCT may be connected to a scan signal line GL, the source electrode may be connected to the first node N1, and the drain electrode may be electrically connected to the data line DL.

In an example where the scan transistor SCT is an n-type transistor, a turn-on level voltage of the scan signal SC may be a high level voltage. In an example where the scan transistor SCT is a p-type transistor, the turn-on level voltage of the scan signal SC may be a low level voltage.

The storage capacitor Cst may be connected between the first node N1 and the second node N2. The storage capacitor Cst can store the amount of electric charge corresponding to a voltage difference between both terminals and maintain the voltage difference between both terminals for a predetermined frame time period. According this configuration, each subpixel SP can emit light for a corresponding frame time period.

The sensing transistor SENT can be turned on by a sense signal SE having a turn-on level voltage, and transfer a reference voltage Vref delivered through a reference voltage line RVL to the second node N2 of the driving transistor DRT. A gate electrode of the sensing transistor SENT may be connected to a sense signal line SENL, a source electrode may be connected to the second node N2, and a drain electrode may be connected to the reference voltage line RVL.

For example, the sensing transistor SENT may transfer a voltage of the second node N2 of the driving transistor DRT to the reference voltage line RVL when a corresponding subpixel SP is driven to sense one or more characteristic values of the subpixel SP. In this example, the voltage transferred to the reference voltage line RVL may be a voltage to calculate a characteristic value of the subpixel SP or a voltage reflecting the characteristic value of the subpixel SP.

Herein, characteristic values of subpixels SP may be characteristic values of driving transistors DRT or light emitting elements ED. The characteristic values of the driving transistors DRT may include threshold voltages and/or mobilities of the driving transistors DRT. The characteristic values of the light emitting elements ED may include threshold voltages of the light emitting element ED.

Each of the driving transistor DRT, the scan transistor SCT, and the sensing transistor SENT may be an n-type transistor or a p-type transistor.

The structure of the subpixel SP illustrated in FIG. 2 is only an example, and may be variously modified by including one or more additional transistors or one or more additional capacitors.

It should be noted that although FIG. 2 illustrates the subpixel structure based on the display device 100 implemented as a self-emissive display device, however, when the display device 100 is implemented as a liquid crystal display device, each subpixel SP may include a transistor, a pixel electrode, and the like.

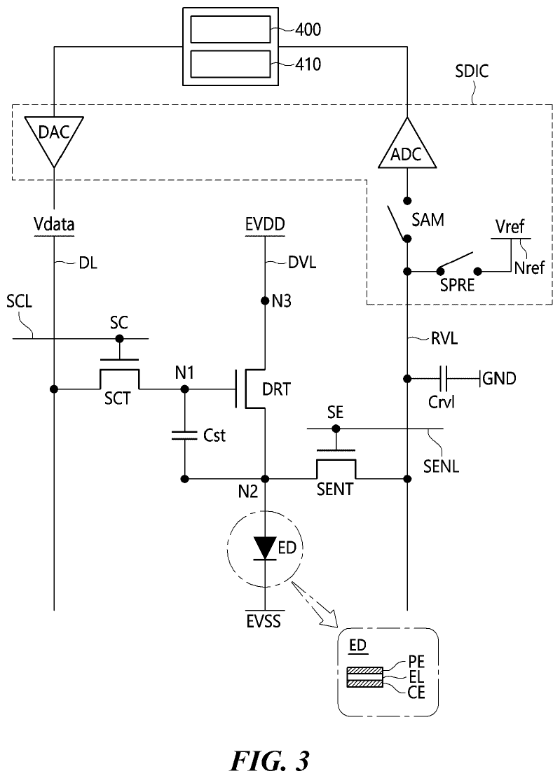

FIG. 3 illustrates an example compensation circuit of the display device 100 according to aspects of the present disclosure.

Referring to FIG. 3, in one or more example embodiments, the compensation circuit of the display device 100 may be a circuit for sensing, and compensating for, one or more characteristic values of one or more circuit elements in one or more subpixels SP.

The compensation circuit may be connected to one or more subpixels SP and may include a power switch SPRE, a sampling switch SAM, an analog-to-digital converter ADC, a compensator 400, and the like.

The power switch SPRE can control a connection between a reference voltage line RVL and a reference voltage supply node Nref. A reference voltage Vref supplied by a power supply device may be supplied to the reference voltage supply node Nref, and the reference voltage Vref applied to the reference voltage supply node Nref may be applied to the reference voltage line RVL through the power switch SPRE.

The sampling switch SAM can control a connection between the analog-to-digital converter ADC and the reference voltage line RVL. When the analog-to-digital converter ADC may be connected to the reference voltage line RVL by the sampling switch SAM, the analog-to-digital converter ADC can convert a voltage (analog voltage) of the connected reference voltage line RVL into a sensing value corresponding to a digital value.

A line capacitor Crvl can be formed between the reference voltage line RLV and the ground GND. A voltage of the reference voltage line RVL may correspond to a quantity of charges stored in the line capacitor Crvl.

An analog-to-digital converter ADC can provide sensing data including a sensing value to the compensator 400.

The compensator 400 can detect a characteristic value of the light emitting element ED or the driving transistor DRT included in the corresponding subpixel SP based on the sensing data, calculate a compensation value, and store the calculated compensation value in a memory 410.

For example, the compensation value may include offset and gain values representing a change in data as information for reducing variations in characteristic values of light emitting elements ED or variations in characteristic values of driving transistors DRT.

The controller 140 can change image data using a compensation value stored in the memory 410 and supply the changed image data to the data driving circuit 120.

The data driving circuit 120 can convert the changed image data into an analog data voltage Vdata using a digital-to-analog converter DAC, and thereafter, output the resulting data voltage Vdata. According to these configurations, compensation can be realized.

Referring to FIG. 3, the analog-to-digital converter ADC, the power switch SPRE, and the sampling switch SAM may be included in a source driver integrated circuit SDIC included in the data driving circuit 120. The compensator 400 may be included in the controller 140.

As described above, an advantage of the display device 100 is that it can perform the compensation for reducing variations in characteristic values of driving transistors DRT. Further, another advantage of the display device 100 is that it can perform sensing driving to detect variations in characteristic values of driving transistors DRT to perform the compensation.

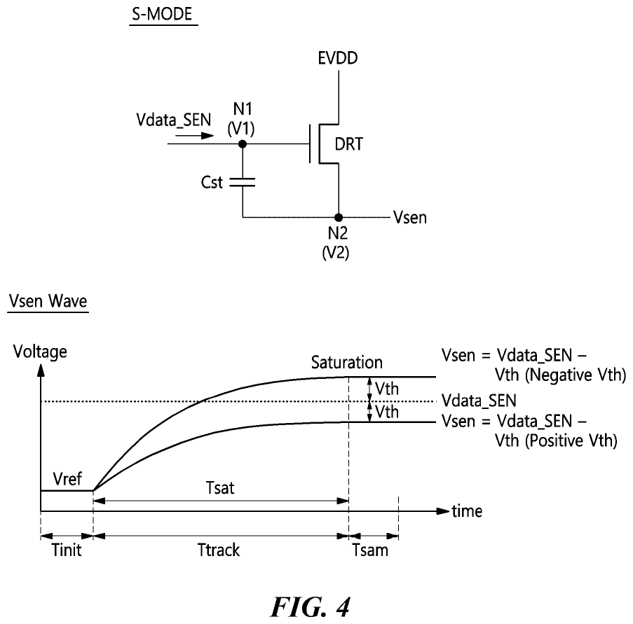

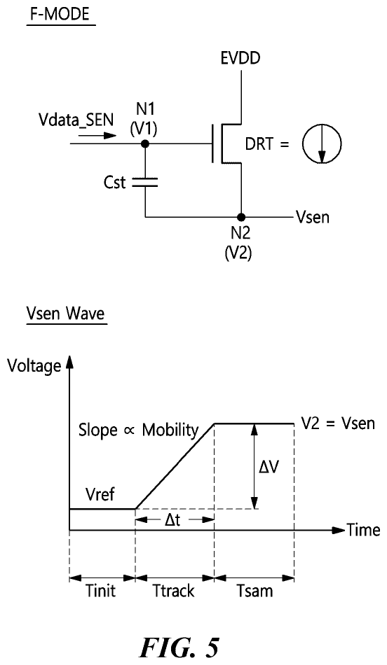

The display device 100 may perform sensing driving in two modes (fast mode and slow mode). Hereinafter, the sensing driving in the two modes (fast mode, slow mode) is described with reference to FIGS. 4 and 5.

FIG. 4 illustrates an example first sensing mode (S-Mode) of the display device 100 according to aspects of the present disclosure. FIG. 5 illustrates an example second sensing mode (F-Mode) of the display device 100 according to aspects of the present disclosure.

Referring to FIGS. 4 and 5, each of a sensing driving period of the first sensing mode (S-Mode) and a sensing driving period of the second sensing mode (F-Mode) may include an initialization sub-period Tinit, a tracking sub-period Ttrack, and a sampling sub-period Tsam.

First, the sensing driving period of the first sensing mode S-Mode of the display device 100 is described with reference to FIGS. 3 and 4.

During the initialization sub-period Tinit, a voltage V1 of the first node N1 of the driving transistor DRT can be initialized to a sensing driving data voltage Vdata_SEN, and a voltage V2 of the second node N2 of the driving transistor DRT can be initialized to a sensing driving reference voltage Vref.

During the initialization sub-period Tinit, the scan transistor SCT and the sensing transistor SENT can be turned on, and the power switch SPRE can be turned on.

During the tracking sub-period Ttrack, while the first node N1 of the driving transistor DRT is in a constant voltage difference state with the sensing driving data voltage Vdata_SEN, the second node N2 of the driving transistor DRT can be electrically floating. Accordingly, during the tracking sub-period Ttrack, the voltage V2 of the second node N2 of the driving transistor DRT can vary.

As the latter half of the tracking sub-period Ttrack progresses, an increasing width of the voltage V2 of the second node N2 of the driving transistor DRT can be reduced, and the voltage V2 of the second node N2 of the driving transistor DRT can be eventually saturated.

When the voltage V2 of the second node N2 of the driving transistor DRT is saturated, the sampling sub-period Tsam can be initiated.

Referring to FIG. 4, the sampling sub-period Tsam of the sensing driving period in the first sensing mode may be a period for measuring a voltage (i.e., Vdata_SEN-Vth, Vdata_SEN-ΔVth) containing the threshold voltage Vth of the driving transistor DRT or a shift in the threshold voltage Vth.

Next, the sensing driving period of the second sensing mode F-Mode of the display device 100 is described with reference to FIGS. 3 and 5.

During the initialization sub-period Tinit, a voltage V1 of the first node N1 of the driving transistor DRT can be initialized to a sensing driving data voltage Vdata_SEN, and a voltage V2 of the second node N2 of the driving transistor DRT can be initialized to a sensing driving reference voltage Vref.

During the tracking sub-period Ttrack, the preset tracking time Δt may be set to a relatively short time. Therefore, it may be difficult for the voltage V2 of the second node N2 of the driving transistor DRT to reach a saturated state that reflects the threshold voltage Vth of the driving transistor DRT for a short tracking time Δt. To address this issue, the voltage V2 of the second node N2 of the driving transistor DRT can be changed enough to determine the mobility of the driving transistor DRT for such a short tracking time Δt.

During the tracking sub-period Ttrack, the voltage V2 of the second node N2 of the driving transistor DRT can increase. In this situation, the voltage V1 of the first node N1 of the driving transistor DRT can also increase.

After the tracking sub-period Ttrack progresses for the preset tracking time Δt, that is, after the voltage V2 of the second node N2 of the driving transistor DRT increases for the preset tracking time Δt, the sampling sub-period Tsam can proceed

When the display device 100 supplies a data voltage Vdata for display driving to a corresponding subpixel SP, the display device 100 can supply a changed data voltage Vata based on a threshold voltage compensation value and a mobility compensation value.

As described above, the threshold voltage sensing may proceed in the first sensing mode S-Mode due to its characteristic requiring a long sensing time, and the mobility sensing can proceed in the second sensing mode F-Mode due to its characteristic requiring a short sensing time.

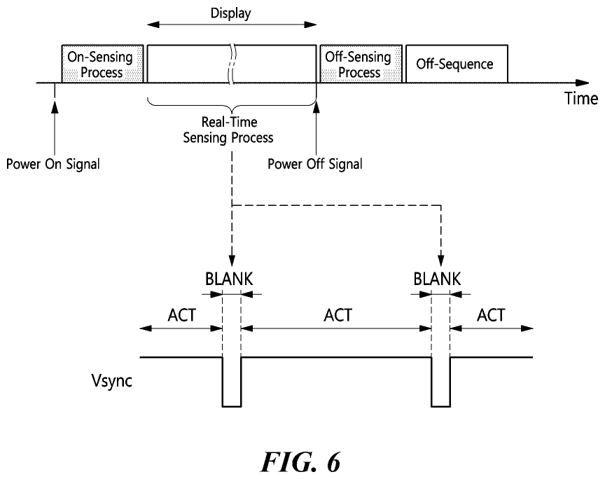

FIG. 6 illustrates example sensing timings of the display device 100 according to aspects of the present disclosure.

Referring to FIG. 6, in one or more example embodiments, the display device 100 can sense one or more characteristic values of a driving transistor DRT in each subpixel SP disposed in the display panel 110 when a power-on signal (Power On Signal) is generated. This sensing process may be referred to as an “on-sensing process”.

Referring to FIG. 6, in one or more aspects, when a power-off signal is generated, before an off-sequence such as switch-off of power proceeds, the display device 100 can also sense respective characteristic values of corresponding driving transistors of all or one or more of the plurality subpixels SP disposed in the display panel 110. This sensing process may be referred to as an “off-sensing process”.

Referring to FIG. 6, in one or more aspects, while display driving is being performed after the power-on signal is generated and before the power-off signal is generated, the display device 100 can also sense respective characteristic values of corresponding driving transistors of all or one or more of the plurality subpixels SP. This sensing process may be referred to as a “real-time sensing process”.

The real-time sensing process may be performed every blank period BLANK between active periods ACT based on a vertical synchronization signal Vsync.

As discussed above, a relatively short period of time may be sufficient for sensing the mobility of a driving transistor DRT, and therefore, mobility sensing may be performed in the second sensing mode, which is the faster sensing mode among the two sensing modes.

Since a relatively short period of time is sufficient for mobility sensing, mobility sensing may be performed using any one of the on-sensing process, the off-sensing process, and the real-time sensing process.

For example, mobility sensing, which may be performed in the second sensing mode, may be performed in the real-time sensing process that can reflect a variance in mobility in real time while the display is being driving. Accordingly, mobility sensing may be performed every blank period BLANK while the display is being driven.

As discussed above, threshold voltage sensing of a driving transistor DRT may require a relatively long sensing time including a long saturation time Vsat. Accordingly, threshold voltage sensing may be performed in the first sensing mode corresponding to the slow sensing mode among the two sensing modes.

Since threshold voltage sensing has a relatively long sensing time, threshold voltage sensing is desired to be performed using timing that does not interfere with the user's viewing. Accordingly, threshold voltage sensing of a driving transistor DRT may be performed after a power-off signal is generated by an input event from a user, and the like. For example, the threshold voltage sensing may be performed in a period during which the display device 100 is not driven for display image or a situation in which the user has no intention of viewing. In this manner, threshold voltage sensing may be performed using the off-sensing process.

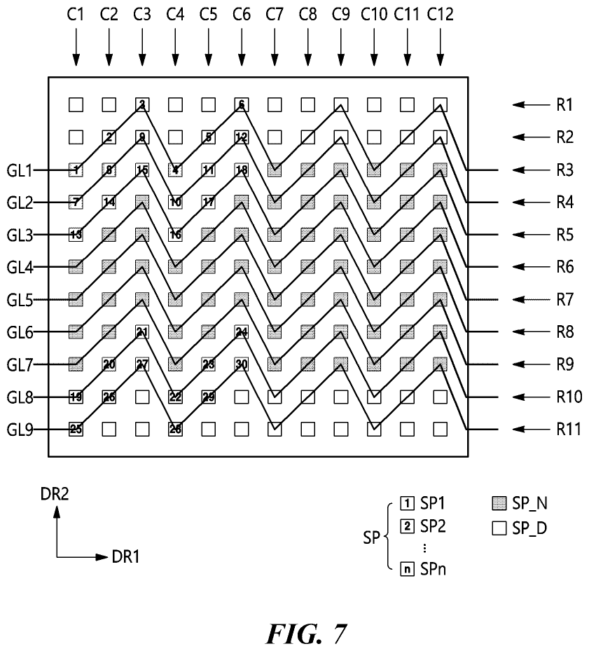

FIG. 7 illustrates an example configuration of a plurality of subpixels in the display panel 110 according to aspects of the present disclosure.

Referring to FIG. 7, in one or more example embodiments, a plurality of subpixels SP may be disposed in the display panel 110. The plurality of subpixes SP may be disposed in a matrix form. It should be noted here that for merely convenience of description, the plurality of subpixes SP are illustrated as being disposed in a first row R1 to an eleventh row R11 and a first column C1 to a twelfth column C12. In one or more aspects, the plurality of pixels may be disposed in various shapes, such as a diamond, a rhombus, or the like.

Referring to FIG. 7, the plurality of subpixes SP may include one or more normal subpixels SP_N and one or more dummy subpixels SP_D. Each normal subpixel SP_N may be a subpixel SP for emitting light, and each dummy subpixel SP_D may be a subpixel SP that cannot emit light.

For example, a plurality of subpixes SP may need to emit light for displaying one image. In this configuration, one image can be presented by one or more normal subpixels SP_N. In contrast, when one image is presented, the dummy subpixel SP_D may not emit light.

Dummy subpixels SP_D may be disposed, for example, in the first row R1, the second row R2, the tenth row R10, and the eleventh row R11. Normal subpixels SP_N may be disposed between the dummy subpixels SP_D. Normal subpixels SP_N may be disposed in the third row R3 to the ninth row R9.

Referring to FIG. 7, a plurality of gate lines GL may be disposed in subpixels SP. The plurality of gate lines GL may extend in a first direction DR1 in a zigzag or staggered pattern. In the plan view illustrated in FIG. 7, the first direction DR1 may be a horizontal direction, and a second direction DR2 may be a vertical direction. For convenience of description, the plurality of gate lines GL are illustrated as including first to ninth gate lines (GL1, . . . , GL9).

The electrical connection relationship of the plurality of subpixes SP and the gate lines GL is as follows. Dummy subpixels may be disposed in the first row, the second row, and the third row. Normal subpixels may be disposed in the third row to an (n+3)^{th} row (n is a natural number greater than or equal to 1). Dummy subpixels may be disposed in an (n+4)^{th} row, an (n+5)^{th} row, and an (n+6)^{th} row.

Dummy subpixels SP_D disposed in the first row and a 3k^{th} column (k is a natural number greater than or equal to 1), dummy subpixels SP_D disposed in the second row and a 3(k−1)^{th} column, and normal subpixels SP_N disposed in the third row and a 3(k−2)^{th} column may be electrically connected to the first gate line GL1 together. Electrical connection relationships between gate lines GL and subpixels SP in the remaining rows and columns may be substantially the same as the foregoing configuration. In this regard, it should be understood that there may be a difference in the presence or absence of, and the number of, connections of dummy subpixels SP_D and normal subpixels SP_N to each other, which can be clearly understood as shown in FIG. 7.

Referring to FIG. 7, gate lines may extend in the first direction while running in the zigzag or staggered pattern according to the foregoing connection relationship. The foregoing configurations are based on an example where subpixels SP are disposed in a matrix form, but may also be applied to subpixels disposed in other patterns such as a diamond, a rhombus, and the like. Hereinafter, the foregoing configurations are described in more detail based on the configuration of FIG. 7.

Referring to FIG. 7, the first gate line GL1 may be electrically connected to first to sixth subpixels (SP1 to SP6).

The first subpixel SP1 may be disposed in the third row R3 and the first column C1. The first subpixel SP1 may be a normal subpixel SP_N.

The second subpixel SP2 may be disposed in the second row R2 and the second column C2. The second subpixel SP2 may be a dummy subpixel SP_D.

The third subpixel SP3 may be disposed in the first row R1 and the third column C3. The third subpixel SP3 may be a dummy subpixel SP_D.

The fourth subpixel SP4 may be disposed in the third row R3 and the fourth column C4. The fourth subpixel SP4 may be a normal subpixel SP_N.

The fifth subpixel SP5 may be disposed in the second row R2 and the fifth column C5. The fifth subpixel SP5 may be a dummy subpixel SP_D.

The sixth subpixel SP6 may be disposed in the first row R1 and the sixth column C6. The sixth subpixel SP6 may be a dummy subpixel SP_D.

The first gate line GL1 may extend from a position of the third row R3 and the first column C1 to a position of the first row R1 and the third column C3. The first gate line GL1 may extend in a diagonal direction.

The first gate line GL1 may extend from the position of the first row R1 and the third column C3 to the position of third row R3 and the fourth column C4.

The first gate line GL1 may extend in the first direction DR1 while repeating the foregoing pattern.

The foregoing discussions have been provided based on the configuration where the first gate line GL1 is electrically connected to the dummy subpixels SP_D. It should be noted that dummy subpixels SP_D may not be disposed in the display panel 110, and in this configuration, the first gate line GL1 may be electrically connected only to the normal subpixels SP_N.

Referring to FIG. 7, the second gate line GL2 may be electrically connected to seventh to twelfth subpixels (SP7 to SP12).

The seventh subpixel SP7 may be disposed in the fourth row R4 and the first column C1. The seventh subpixel SP7 may be a normal subpixel SP_N.

The eighth subpixel SP8 may be disposed in the third row R3 and the second column C2. The eighth subpixel SP8 may be a normal subpixel SP_N.

The ninth subpixel SP9 may be disposed in the second row R2 and the third column C3. The ninth subpixel SP9 may be a dummy subpixel SP_D.

The tenth subpixel SP10 may be disposed in the fourth row R4 and the fourth column C4. The tenth subpixel SP10 may be a normal subpixel SP_N.

The eleventh subpixel SP11 may be disposed in the third row R3 and the fifth column C5. The eleventh subpixel SP11 may be a normal subpixel SP_N.

The twelfth subpixel SP12 may be disposed in the second row R2 and the sixth column C6. The 12th subpixel SP12 may be a dummy subpixel SP_D.

The second gate line GL2 may extend from a position of the fourth row R4 and the first column C1 to a position of the second row R2 and the third column C3. The second gate line GL2 may extend in a diagonal direction.

The second gate line GL2 may extend from the position of the second row R2 and the third column C3 to the position of the fourth row R4 and the fourth column C4.

The second gate line GL2 may extend in the first direction DR1 while repeating the foregoing pattern.

The foregoing discussions have been provided based on the configuration where the second gate line GL2 is electrically connected to the dummy subpixels SP_D. It should be noted that dummy subpixels SP_D may not be disposed in the display panel 110, and in this configuration, the second gate line GL2 may be electrically connected only to the normal subpixels SP_N.

Referring to FIG. 7, the third gate line GL3 may be electrically connected to thirteenth to eighteenth subpixels (SP13 to SP18).

The thirteenth subpixel SP13 may be disposed in the fifth row R5 and the first column C1. The thirteenth subpixel SP13 may be a normal subpixel SP_N.

The fourteenth subpixel SP14 may be disposed in the fourth row R4 and the second column C2. The fourteenth subpixel SP14 may be a normal subpixel SP_N.

The fifteenth subpixel SP15 may be disposed in the third row R3 and the third column C3. The fifteenth subpixel SP15 may be a normal subpixel SP_N.

The sixteenth subpixel SP16 may be disposed in the fifth row R5 and the fourth column C4. The sixteenth subpixel SP16 may be a normal subpixel SP_N.

The seventeenth subpixel SP17 may be disposed in the fourth row R4 and the fifth column C5. The seventeenth subpixel SP17 may be a normal subpixel SP_N.

The eighteenth subpixel SP18 may be disposed in the third row R3 and the sixth column C6. The eighteenth subpixel SP18 may be a normal subpixel SP_N.

The third gate line GL3 may extend from a position of the fifth row R5 and first column C1 to a position of the third row R3 and third column C3. The third gate line GL3 may extend in a diagonal direction.

The third gate line GL3 may extend from the position of the third row R3 and third column C3 to the position of the fifth row R5 and the fourth column C4.

The third gate line GL3 may extend in the first direction DR1 while repeating the foregoing pattern.

Since the feature of the third gate line GL3 is the same as those of the fourth gate line GL4 to the seventh gate line GL7, repeated descriptions are omitted.

Referring to FIG. 7, the eighth gate line GL8 may be electrically connected to nineteenth to twenty-fourth subpixels (SP19 to SP24).

The nineteenth subpixel SP19 may be disposed in the tenth row R10 and the first column C1. The nineteenth subpixel SP19 may be a dummy subpixel SP_D.

The twentieth subpixel SP20 may be disposed in the ninth row R9 and the second column C2. The twentieth subpixel SP20 may be a normal subpixel SP_N.

The twenty-first subpixel SP21 may be disposed in the eighth row R8 and the third column C3. The twenty-first subpixel SP21 may be a normal subpixel SP_N.

The twenty-second subpixel SP22 may be disposed in the tenth row R10 and the fourth column C4. The twenty-second subpixel SP22 may be a dummy subpixel SP_D.

The twenty-third subpixel SP23 may be disposed in the ninth row R9 and the fifth column C5. The twenty-third subpixel SP23 may be a normal subpixel SP_N.

The twenty-fourth subpixel SP24 may be disposed in the eighth row R8 and the sixth column C6. The twenty-fourth subpixel SP24 may be a normal subpixel SP_N.

The eighth gate line GL8 may extend from a position of the tenth row R10 and the first column C1 to a position of the eighth row R8 and the third column C3. The eighth gate line GL8 may extend in a diagonal direction.

The eighth gate line GL8 may extend from the position of the eighth row R8 and the third column C3 to the position of the tenth row R10 and the fourth column C4.

The eighth gate line GL8 may extend in the first direction DR1 while repeating the foregoing pattern.

The foregoing discussions have been provided based on the configuration where the eighth gate line GL8 is electrically connected to the dummy subpixels SP_D. It should be noted that dummy subpixels SP_D may not be disposed in the display panel 110, and in this configuration, the eighth gate line GL8 may be electrically connected only to the normal subpixels SP_N.

Referring to FIG. 7, the nine gate line GL9 may be electrically connected to twenty-fifth to thirtieth subpixels (SP25 to SP30).

The twenty-fifth subpixel SP25 may be disposed in the eleventh row R11 and the first column C1. The twenty-fifth subpixel SP25 may be a dummy subpixel SP_D.

The twenty-sixth subpixel SP26 may be disposed in the tenth row R10 and the second column C2. The twenty-sixth subpixel SP26 may be a dummy subpixel SP_D.

The twenty-seventh subpixel SP27 may be disposed in the ninth row R9 and the third column C3. The twenty-seventh subpixel SP27 may be a normal subpixel SP_N.

The twenty-eighth subpixel SP28 may be disposed in the eleventh row R11 and the fourth column C4. The twenty-eighth subpixel SP28 may be a dummy subpixel SP_D.

The twenty-ninth subpixel SP29 may be disposed in the tenth row R10 and the fifth column C5. The twenty-ninth subpixel SP29 may be a dummy subpixel SP_D.

The thirtieth subpixel SP30 may be disposed in the ninth row R9 and the sixth column C6. The thirtieth subpixel SP30 may be a normal subpixel SP_N.

The ninth gate line GL9 may extend from a position of the eleventh row R11 and the first column C1 to a position of the ninth row R9 and the third column C3. The ninth gate line GL9 may extend in a diagonal direction.

The ninth gate line GL9 may extend from the position of the ninth row R9 and the third column C3 to the position of the eleventh row R11 and the fourth column C4.

The ninth gate line GL9 may extend in the first direction DR1 while repeating the foregoing pattern.

The foregoing discussions have been provided based on the configuration where the ninth gate line GL9 is electrically connected to the dummy subpixels SP_D. It should be noted that dummy subpixels SP_D may not be disposed in the display panel 110, and in this configuration, the ninth gate line GL9 may be electrically connected only to the normal subpixels SP_N.

A sense signal line SENL illustrated in FIG. 2 may be located adjacent to each of the plurality of gate lines GL. The characteristics of a plurality of sense signal lines SENL may be the same as the characteristics of the plurality of gate lines GL. The arrangement of the plurality of sense signal lines SENL may be the same as the arrangement of the plurality of gate lines GL. The connection relationship of the plurality of sense signal lines SENL with the subpixels SP may be the same as the connection relationship of the plurality of gate lines GL with the subpixels SP. Therefore, description related to the sense signal lines SENL is omitted for conciseness.

As described above, the arrangement and connection relationship of the plurality of gate lines GL have been provided. Hereinafter, discussions for more detailed configurations of subpixels SP are provided.

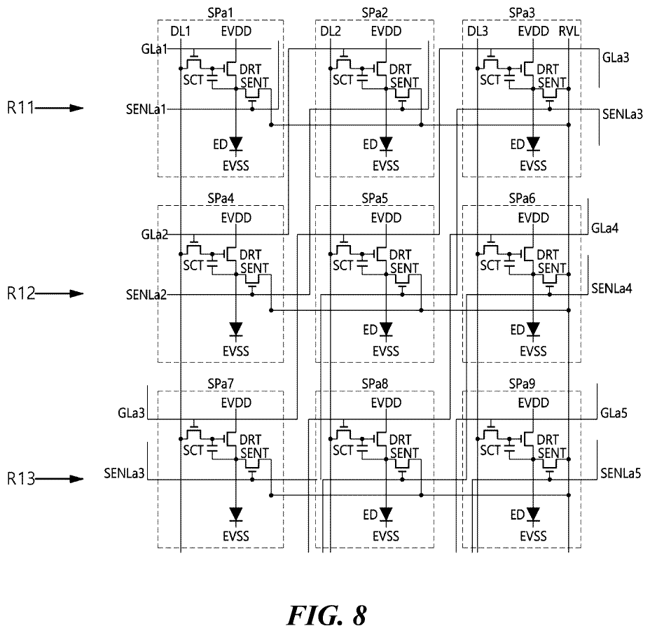

FIG. 8 illustrates an example structure of a plurality of subpixels SP according to aspects of the present disclosure.

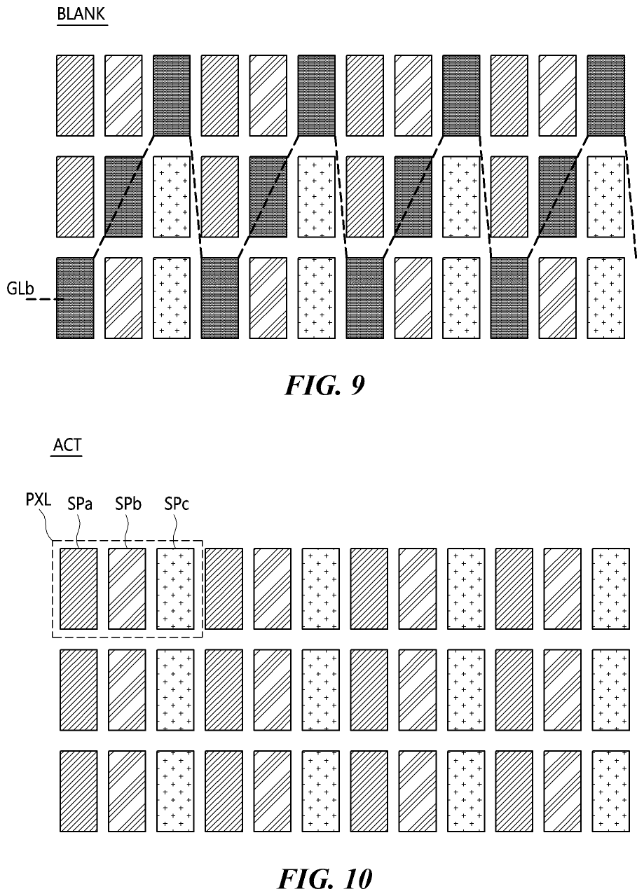

FIG. 9 illustrates an example characteristic value sensing for subpixels SP according to aspects of the present disclosure.

Referring to FIG. 8, in one or more example embodiments, the display panel 110 may include a plurality of subpixels SPa. For convenience of description, discussions are provided for nine subpixels SPa.

Referring to FIG. 8, subpixels SPa may be electrically connected to data lines DL, gate lines GLa, sense signal lines SENLa, at least one driving voltage line DVL, at least one base voltage line SVL, and at least one reference voltage line RVL. Each of the subpixels SPa may include a driving transistor DRT, a scan transistor SCT, a sensing transistor SENT, a storage capacitor Cst, and a light emitting element ED. The structure of each of the subpixels SPa may be the same as that of the subpixel SP of FIG. 2. Hereinafter, for convenience of description, although description is provided such that the subpixels SPa may be electrically connected to the data lines DL, the gate lines GLa, the sense signal lines SENLa, the at least one driving voltage line DVL, the at least one base voltage line SVL, and the at least one reference voltage line RVL, it should be understood that these lines may be electrically connected to components inside of the subpixels SPa.

Referring to FIG. 8, a first subpixel SPa1, a second subpixel SPa2, and a third subpixel SPa3 may be disposed in a first row R11. A fourth subpixel SPa4, a fifth subpixel SPa5, and a sixth subpixel SPa6 may be disposed in a second row R12. A seventh subpixel SPa7, an eighth subpixel SPa8, and a ninth subpixel SPa9 may be disposed in a third row R13.

Referring to FIG. 8, the first subpixel SPa1, the fourth subpixel SPa4, and the seventh subpixel SPa7 may be disposed in a first column C11. The second subpixel SPa2, the fifth subpixel SPa5, and the eighth subpixel SPa8 may be disposed in a second column C12. The third subpixel SPa3, the sixth subpixel SPa6, and the ninth subpixel SPa9 may be disposed in a third column C13.

Referring to FIG. 8, a first data line DL1 may be electrically connected to the first subpixel SPa1, the fourth subpixel SPa4, and the seventh subpixel SPa7. A second data line DL2 may be electrically connected to the second subpixel SPa2, the fifth subpixel SPa5, and the eighth subpixel SPa8. A third data line DL3 may be electrically connected to the third subpixel SPa3, the sixth subpixel SPa6, and the ninth subpixel SPa9.

Referring to FIG. 8, a reference voltage line RVL may be electrically connected to the nine subpixels SPa. The nine subpixels SPa may share one reference voltage line RVL.

Referring to FIGS. 7 and 8, a plurality of gate lines GLa may be disposed to extend in a zigzag pattern or a diagonal direction rather than in a straight line. Referring to FIG. 8, a plurality of sense signal lines SENLa may be disposed to extend in the zigzag pattern or the diagonal direction rather than in the straight line.

Referring to FIG. 8, a first gate line GLa1 and a first sense signal line SENLa1 may be electrically connected to the first subpixel SPa1.

Referring to FIG. 8, a second gate line GLa2 and a second sense signal line SENLa2 may be electrically connected to the second subpixel SPa2 and the fourth subpixel SPa4.

Referring to FIG. 8, a third gate line GLa3 and a third sense signal line SENLa3 may be electrically connected to the third subpixel SPa3, the fifth subpixel SPa5, and the seventh subpixel SPa7.

Referring to FIG. 8, a fourth gate line GLa4 and a fourth sense signal line SENLa4 may be electrically connected to the sixth subpixel SPa6 and the eighth subpixel SPa8.

Referring to FIG. 8, a fifth gate line GLa5 and a fifth sense signal line SENLa5 may be electrically connected to the ninth subpixel SPa9.

Sensing characteristic values for the subpixels SPa may be performed for subpixels SPa electrically connected to the same gate line GLa.

The subpixels SPa electrically connected to the same gate line GLa may be disposed in the zigzag pattern instead of being disposed in a row direction. A reset (RT) line visible phenomenon may be easily recognized by users when a black line appears in the row direction. If a black line in a zigzag pattern, the RT line visible phenomenon may not be easily recognized by users. However, although it is illustrated in the drawing that the gate lines extend in the row direction with a zigzag pattern, the present disclosure is not limited to it. In an alternative embodiment, the gate lines may also extend in the column direction with a zigzag pattern.

Referring to FIG. 9, in one or more example embodiments, subpixels SP may be electrically connected to a specific gate line GLb, and characteristic value sensing may be performed for these subpixels SP. The subpixels SP on which characteristic value sensing is performed may present a low-gray level or black. In this configuration, the subpixes SP on which characteristic value sensing is performed may be disposed in the zigzag pattern, and therefore, the RT line visibility phenomenon may not be recognized by users.

Hereinafter, characteristic value sensing driving in a blank period BLANK is discussed based on the nine subpixels SPa illustrated in FIG. 8 as an example.

For example, in a first blank period BLANK, characteristic value sensing may be performed for the first subpixel SPa1 electrically connected to the first gate line GLa1. A turn-off gate signal may be supplied to the remaining gate lines GLa except for the first gate line GLa1. Accordingly, the subpixels SPa electrically connected to the remaining gate lines GLa may not be supplied with a sensing driving data voltage. In this configuration, the first subpixel SPa1 may receive the sensing driving data voltage, and a sensing value for a characteristic value of the first subpixel SPa1 may be transmitted to the data driving circuit through the reference voltage line RVL.

For example, in a second blank period BLANK, characteristic value sensing may be performed for the second subpixel SPa2 and the fourth subpixel SPa4 electrically connected to the second gate line GLa2. The second subpixel SPa2 and the fourth subpixel SPa4 may receive the sensing driving data voltage, and sensing values for characteristic values of these subpixels (SPa2 SPa4) may be transmitted to the data driving circuit through the reference voltage line RVL. In this configuration, the remaining subpixels SPa may not receive the sensing driving data voltage.

For example, in a third blank period BLANK, characteristic value sensing may be performed for the third subpixel SPa3, the fifth subpixel SPa5, and the seventh subpixel SPa7, which are electrically connected to the third gate line GLa3. The third subpixel SPa3, the fifth subpixel SPa5, and the seventh subpixel SPa7 may receive the sensing driving data voltage, and sensing values for characteristic values of these subpixels (SPa3, SPa5, and SPa7) may be transmitted to the data driving circuit through the reference voltage line RVL. In this configuration, the remaining subpixels SPa may not receive the sensing driving data voltage.

For example, in a fourth blank period BLANK, characteristic value sensing may be performed for the sixth subpixel SPa6 and the eighth subpixel SPa8, which are electrically connected to the fourth gate line GLa4. The sixth subpixel SPa6 and the eighth subpixel SPa8 may receive the sensing driving data voltage, and sensing values for characteristic values of these subpixels (SPa6 and SPa8) may be transmitted to the data driving circuit through the reference voltage line RVL. In this configuration, the remaining subpixels SPa may not receive the sensing driving data voltage.

For example, in a fifth blank period BLANK, characteristic value sensing may be performed for the ninth subpixel SPa9 electrically connected to the fifth gate line GLa5. The ninth subpixel SPa9 may receive the sensing driving data voltage, and a sensing value for a characteristic value of the ninth subpixel SPa9 may be transmitted to the data driving circuit through the reference voltage line RVL. In this configuration, the remaining subpixels SPa may not receive the sensing driving data voltage.

Next, discussions are provided for the driving of the subpixels SPa for light emission in an active period ACT.

Scan signals may be sequentially supplied to the plurality of gate lines GLa. For example, after a turn-on scan signal is supplied to the first gate line GLa1, a turn-on scan signal may be supplied to the second gate line GLa2. Thereafter, a turn-on scan signal may be supplied to the third gate line GLa3. Discussions for the fourth gate line GLa4 and the fifth gate line GLa5 are omitted for convenience of description.

When the subpixels SPa are supplied with turn-on scan signals through the gate lines GLa, data signals can be supplied to the data lines DL connected to the subpixels SPa.

When the turn-on scan signal is supplied to the first gate line GLa1, only the first subpixel SPa1 can be supplied with the turn-on scan signal. The first subpixel SPa1 can be supplied with a data voltage through the first data line DL1. Subpixels SPa electrically connected to the first gate line GLa1 may be supplied with data voltages through data lines DL different from each other.

When the turn-on scan signal is supplied to the second gate line GLa2, the second subpixel SPa2 and the fourth subpixel SPa4 can be supplied with the turn-on scan signal. The second subpixel SPa2 can be supplied with a data voltage through the second data line DL2, and the fourth subpixel SPa4 can be supplied with a data voltage through the first data line DL1. Subpixels SPa electrically connected to the second gate line GLa2 may be supplied with data voltages through data lines DL different from each other.

When the turn-on scan signal is supplied to the third gate line GLa3, the third subpixel SPa3, the fifth subpixel SPa5, and the seventh subpixel SPa7 can be supplied with the turn-on scan signal. The third subpixel SPa3 can be supplied with a data voltage through the third data line DL3, the fifth subpixel SPa5 can be supplied with a data voltage through the second data line DL2, and the seventh subpixel SPa7 can be supplied with a data voltage through the first data line DL1.

When the turn-on scan signal is supplied to the fourth gate line GLa4, the sixth subpixel SPa6 and the eighth subpixel SPa8 can be supplied with the turn-on scan signal. The sixth subpixel SPa6 can be supplied with a data voltage through the third data line DL3, and the eighth subpixel SPa8 can be supplied with a data voltage through the second data line DL2.

When the turn-on scan signal is supplied to the fifth gate line GLa5, only the fifth subpixel SPa5 can be supplied with the turn-on scan signal. The fifth subpixel SPa5 can be supplied with a data voltage through the third data line DL3.

When data voltages are supplied to the subpixels SPa, the subpixels SPa may be supplied with a reference voltage through the reference voltage line RVL. A mount of electric charge corresponding to a voltage difference between the data voltage and the reference voltage can be stored in the storage capacitor Cst. Thereafter, the voltage stored in the storage capacitor Cst can form a voltage between the first node and the second node of the driving transistor DRT, and the driving transistor DRT can cause a driving current corresponding to the voltage stored in the storage capacitor Cst to flow through the light emitting element ED.

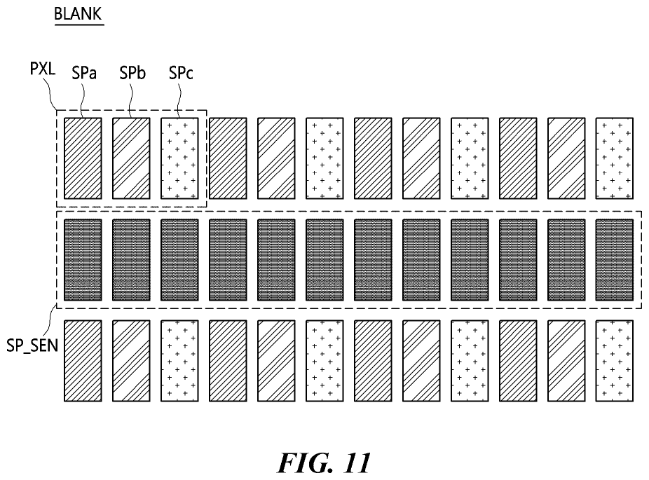

FIGS. 10 and 11 illustrate example light emitting states of the display panel 110. Referring to FIGS. 10 and 11, when characteristic value sensing is performed in a blank period BLANK following an active period ACT, the RT line visible phenomenon may appear in the display panel 110. In contrast, the display device 100 according to the example embodiments of the present disclosure illustrated in FIGS. 7 to 9 has an advantage of preventing or reducing the RT line visible phenomenon.

According to the one or more aspects described herein, the quality of the display panel 110 can be improved through a structure where a gate line at least partially extents along subpixels disposed in different rows.

According to the one or more aspects described herein, the characteristic values of subpixels can be detected and the quality of the display panel 110 can be improved through a structure where a gate line at least partially extents along subpixels disposed in different rows.

According to the one or more aspects described herein, the display panel 110 can be driven in a simplified configuration and driven with low power through a structure where a gate line at least partially extents along subpixels disposed in different rows.

The examples, aspects, and embodiments for the display device 100 and the display panel 110 described herein may be described as follows.

According to the one or more example embodiments described herein, a display device can be provided that includes a plurality of subpixels, a plurality of gate lines connected to the plurality of subpixels, and a plurality of reference voltage lines connected to the plurality of subpixels. In one or more aspects, the plurality of reference voltage lines may include a reference voltage line electrically connected to first to third subpixels, and the plurality of gate lines may include a first gate line electrically connected to the first to third subpixels disposed in a diagonal direction. In one or more aspects, the first subpixel may be located in a third row and a first column, the second subpixel may be located in a second row and a second column, and the third subpixel may be located in a first row and a third column.

In one or more aspects, the first gate line may be disposed in a zigzag pattern a tooth of which is formed by extending the first gate line extends in a direction from a position of the third row and the first column to a position of the first row and the third column, and then extending from the position of the first row and the third column to a position of the third row and a fourth column.

In one or more aspects, the display device may further include a second gate line extending from a position of a fourth row and the first column to a position of the second row and the second column, and then extending from the position of the second row and the second column to a position of the fourth row and a fourth column.

In one or more aspects, the display device may further include a fifth subpixel electrically connected to the second gate line and located in the fourth row and the first column, a sixth subpixel electrically connected to the second gate line and located in the third row and the second column, and a seventh subpixel electrically connected to the second gate line and located in the second row and the third column.

In one or more aspects, during an active period, the first gate line and the second gate line may be sequentially supplied with a turn-on scan signal, and during a blank period after the active period, one of the first gate line and the second gate line may be supplied with the turn-on scan signal.

In one or more aspects, during the blank period, when the turn-on scan signal is supplied to the first gate line, characteristic value sensing of the first to third subpixels electrically connected to the first gate line may be performed.

In one or more aspects, during the blank period, the first to third subpixels may present a low gray level or black.

In one or more aspects, a turn-off scan signal may be supplied to the second gate line during the blank period.

In one or more aspects, the display device may further include a first data line located in a first column and electrically connected to the first subpixel, a second data line located in a second column and electrically connected to the second subpixel, and a third data line located in a third column and electrically connected to the third subpixel.

In one or more aspects, when a turn-on scan signal is supplied through the first gate line, the first subpixel may be supplied with a data voltage through the first data line, and when the turn-on scan signal is supplied through the first gate line, the third subpixel may not be supplied with a data voltage through the third data line.

In one or more aspects, the first subpixel may be a normal subpixel driven when a first image is displayed, and the third subpixel may be a dummy subpixel not driven when the first image is displayed.

In one or more aspects, the display device may further include a plurality of first dummy subpixel groups arranged in a line in the first row adjacent to one side of the display panel, a plurality of first normal subpixel groups arranged in a line in the third row, and a plurality of second dummy subpixel groups arranged in a line in a row adjacent to another side of the display panel opposite to the one side.

In one or more aspects, when a turn-on scan signal is supplied through the first gate line, the first subpixel may be supplied with a first data voltage through the first data line, and when the turn-on scan signal is supplied through the first gate line, the third subpixel may be supplied with a third data voltage through the third data line.

In one or more aspects, the first subpixel and the third subpixel may be normal subpixels driven when a first image is displayed.

In one or more aspects, each of the first to third subpixels may include a light emitting element, a driving transistor electrically connected to the light emitting element, a scan transistor electrically connected between a first node, which is a gate node of the driving transistor, and a data line, and a sensing transistor electrically connected between a second node of the driving transistor and a reference voltage line.

In one or more aspects, during a blank period, threshold voltage and mobility characteristics of the driving transistor may be sensed.

In one or more aspects, the display device may further include a data driving circuit configured to sense a characteristic value of the driving transistor through the reference voltage line electrically connected to the sensing transistor during the blank period.

In one or more aspects, the display device may further include a first sense signal line electrically connected to the first to third subpixels disposed in a diagonal direction.

In one or more aspects, the first sense signal line may be disposed in a zigzag pattern such that the first gate line extends in a direction from a position of the third row and the first column to a position of the first row and the third column, and then extends from the position of the first row and the third column to a position of the third row and a fourth column, and the first sense signal line may extend in a plurality of the zigzag patterns.

In one or more aspects, the display device may further include a fourth subpixel located in the third row and the fourth column. In one or more aspects, the first gate line may be electrically connected to the first subpixel to the third subpixel located in a diagonal direction, and may be electrically connected to the third subpixel and the fourth subpixel located in a direction different from the diagonal direction.

The above description has been presented to enable any person skilled in the art to make, use and practice the technical features of the present disclosure, and has been provided in the context of a particular application and its requirements as examples. Various modifications, additions and substitutions to the described embodiments will be readily apparent to those skilled in the art, and the principles described herein may be applied to other embodiments and applications without departing from the scope of the present disclosure. The above description and the accompanying drawings provide an example of the technical idea of the present disclosure for illustrative purposes only. That is, the disclosed embodiments are intended to illustrate the scope of the technical features of the present disclosure.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a plurality of subpixels;
a plurality of gate lines connected to the plurality of subpixels; and
a plurality of reference voltage lines connected to the plurality of subpixels,
wherein the plurality of reference voltage lines include:
a reference voltage line electrically connected to first to third subpixels, and
wherein the plurality of gate lines include:
a first gate line electrically connected to the first to third subpixels disposed in a diagonal direction.

2. The display device of claim 1, wherein the first subpixel is located in a third row and a first column, the second subpixel is located in a second row and a second column, and the third subpixel is located in a first row and a third column.

3. The display device of claim 2, wherein the first gate line is disposed in a zigzag pattern, a tooth of the zigzag pattern extending in a direction from a position of the third row and the first column to a position of the first row and the third column, and then extending from the position of the first row and the third column to a position of the third row and a fourth column.

4. The display device of claim 2, further comprising a second gate line extending from a position of a fourth row and the first column to a position of the second row and the second column, and then extending from the position of the second row and the second column to a position of the fourth row and a fourth column.

5. The display device of claim 4, further comprising:
a fifth subpixel electrically connected to the second gate line and located in the fourth row and the first column;
a sixth subpixel electrically connected to the second gate line and located in the third row and the second column; and
a seventh subpixel electrically connected to the second gate line and located in the second row and the third column.

6. The display device of claim 5, wherein during an active period, the first gate line and the second gate line are sequentially supplied with a turn-on scan signal, and during a blank period after the active period, one of the first gate line and the second gate line is supplied with the turn-on scan signal.

7. The display device of claim 6, wherein during the blank period, when the turn-on scan signal is supplied to the first gate line, characteristic value sensing of the first to third subpixels electrically connected to the first gate line is performed.

8. The display device of claim 7, wherein during the blank period, the first to third subpixels present a low gray level or black.

9. The display device of claim 7, wherein a turn-off scan signal is supplied to the second gate line during the blank period.

10. The display device of claim 1, wherein the first subpixel is located in a third row and a first column, the second subpixel is located in a second row and a second column, and the third subpixel is located in a first row and a third column, and
wherein the display device further comprises:
a first data line located in the first column and electrically connected to the first subpixel;
a second data line located in the second column and electrically connected to the second subpixel; and
a third data line located in the third column and electrically connected to the third subpixel.

11. The display device of claim 10, wherein when a turn-on scan signal is supplied through the first gate line, the first subpixel is supplied with a data voltage through the first data line, and
the third subpixel is not supplied with a data voltage through the third data line.

12. The display device of claim 11, wherein the first subpixel is a normal subpixel driven when a first image is displayed, and the third subpixel is a dummy subpixel not driven when the first image is displayed.

13. The display device of claim 12, further comprising:
a plurality of first dummy subpixel groups arranged in a line in the first row adjacent to one side of the display panel;
a plurality of first normal subpixel groups arranged in a line in the third row; and
a plurality of second dummy subpixel groups arranged in a line in a row adjacent to another side of the display panel opposite to the one side.

14. The display device of claim 10, wherein when a turn-on scan signal is supplied through the first gate line, the first subpixel is supplied with a first data voltage through the first data line, and the third subpixel is supplied with a third data voltage through the third data line.

15. The display device of claim 14, wherein the first subpixel and the third subpixel are normal subpixels driven when a first image is displayed.

16. A display device comprising:
a plurality of subpixels arranged in a row direction and a column direction;
a gate line electrically connected to subpixels of the plurality of subpixels arranged in different rows and columns from one another; and
a reference voltage line electrically connected to subpixels of the plurality of subpixels arranged in a same row.

17. The display device of claim 16, wherein the gate line is disposed in a plurality of zigzag patterns and extends in the row direction.

18. The display device of claim 16, wherein the plurality of subpixels comprise a plurality of normal subpixels driven when a first image is displayed, and a plurality of dummy subpixels not driven when the first image is displayed.

19. The display device of claim 18, wherein a first gate line is electrically connected to the plurality of normal subpixels and the plurality of dummy subpixels, and a second gate line is electrically connected to the plurality of normal subpixels.

20. The display device of claim 16, wherein each of the plurality of subpixels comprises:
a light emitting element;
a driving transistor electrically connected to the light emitting element;
a scan transistor electrically connected between a first node, which is a gate node of the driving transistor, and a data line; and
a sensing transistor electrically connected between a second node of the driving transistor and a reference voltage line.

21. A display device comprising:
a plurality of subpixels arranged in a row direction and a column direction;
a plurality of gate line each extending in a zigzag shape and electrically connected to subpixels of the plurality of subpixels arranged in a zigzag shape, respectively; and
a reference voltage line electrically connected to subpixels of the plurality of subpixels arranged in a same row.

22. The display device of claim 21, wherein the plurality of gate lines each extends in the row direction or the column direction in a zigzag pattern, respectively.

23. The display device of claim 22, wherein the plurality of gate lines are parallel with each other.

24. The display device of claim 22, a tooth of the zigzag pattern extends in a direction from a subpixel of the third row and the first column to a subpixel of the first row and the third column, and then extends to a subpixel of the third row and a fourth column.
